(19) United States
(12) Patent Application Publication
(10) Pub. No.: US 2020/0249263 A1
(43) Pub. Date: Aug. 6, 2020

(54) METHOD AND TOOL FOR ELECTROSTATIC CHUCKING

(71) Applicant: Applied Materials, Inc., Santa Clara, CA (US)

(72) Inventors: Lu XU, Santa Clara, CA (US); Sarah Michelle BOBEK, Sunnyvale, CA (US); Prashant Kumar KULSHRESHTHA, San Jose, CA (US); Byung Seok KWON, San Jose, CA (US); Venkata Sharat Chandra PARIMI, Santa Clara, CA (US); Kwangduk Douglas LEE, Redwood City, CA (US); Juan Carlos ROCHA-ALVAREZ, San Carlos, CA (US)

(21) Appl. No.: 16/748,640

(22) Filed: Jan. 21, 2020

Related U.S. Application Data
(60) Provisional application No. 62/802,109, filed on Feb. 6, 2019.

(51) Int. Cl. G01R 29/12; C23C 16/52; H01L 21/66; H01J 37/32

(52) U.S. Cl. CPC G01R 29/12; C23C 16/52; H01L 22/14; H01J 2237/2007; H01J 37/32082; H01J 2237/3321; H01J 37/32715

(57) ABSTRACT

Embodiments described herein relate to methods and tools for monitoring electrostatic chucking performance. A performance test is performed that requires only one bowed substrate and one reference substrate. To run the test, the reference substrate is positioned on an electrostatic chuck in a process chamber and the bowed substrate is positioned on the reference substrate. A voltage is applied from a power source to the electrostatic chuck, generating an electrostatic chucking force to secure the bowed substrate to the reference substrate. Thereafter, the applied voltage is decreased incrementally until the electrostatic chucking force is too weak to maintain the bowed substrate in flat form, resulting in dechucking of the bowed wafer. By monitoring the impedance of the chamber during deposition using a sensor, the dechucking threshold voltage can be identified at the point where the impedance of the reference substrate and the impedance of the bowed substrate deviates.

### CROSS-REFERENCE TO RELATED APPLICATIONS

This application claims priority to U.S. Provisional Patent Application No. 62/802,109, filed Feb. 6, 2019, which is herein incorporated by reference in its entirety.

### BACKGROUND

### Field

Embodiments described herein generally relate to methods and tools for monitoring semiconductor processes and, more particularly, to methods and tools for monitoring electrostatic chucking performance within semiconductor processes.

### Description of the Related Art

As memory density increases in semiconductor devices, the wafer bow of a multi-stack structure increases as well. Consequently, a sufficient amount of clamping force is required to securely flatten the wafer and hold its flatness during subsequent plasma enhanced chemical vapor deposition (PECVD) processes. In PECVD chambers, the electrostatic chucking force must be strong enough so that the radio frequency (RF) path is maintained with plasma coupling and RF grounding to the front surface of the wafer only, acting to chuck the bowed wafer to the underlying heater substrate during deposition processes. The warpage of a bowed wafer increases with increasing process temperature; therefore, it is of great importance to establish a reliable method to evaluate the chucking performance of high temperature PECVD processes. The electrostatic chuck performance is a very useful parameter to evaluate because it can provide crucial information on the process chamber hardware and tools.

However, conventional electrostatic chucking performance tests have drawbacks. For example, conventional electrostatic chucking performance tests require the usage of multiple bowed wafers with different film thicknesses. The success criteria for chucking in these tests can be based on the thickness of film deposited on flat compared to bowed wafers to quantify the sustained RF path to ground. As the chucking force is lost and the wafer bow increases, deposition occurs on the wafer backside resulting in the loss of front film thickness.

Although the testing method described above can provide accurate chucking margin of the process chamber, it requires multiple wafer runs and cross-section scanning electron microscopes (SEMs), which are very time consuming. To compare process chamber hardware or process conditions, the test needs to be conducted multiple times to acquire accurate information. Furthermore, for a production PECVD chamber, hardware and process drift over time is a common issue. To monitor chamber condition over time, multiple tests need to be conducted throughout chamber production to ensure chamber stability over an extended period of time, adding more downtime and requiring more periodic maintenance for the chamber.

Accordingly, there is a need for a new and more efficient test to monitor electrostatic chucking performance within semiconductor processes.

### SUMMARY

One or more embodiments described herein generally relate to methods and tools for monitoring electrostatic chucking performance within semiconductor processes.

In one embodiment, a method for monitoring electrostatic chucking performance includes positioning a reference substrate on an electrostatic chuck in a process chamber; positioning a bowed substrate on the reference substrate; applying a power to an electrode in the electrostatic chuck; monitoring an impedance of the reference substrate and an impedance of the bowed substrate using the sensor; and incrementally decreasing a voltage of the power until the impedance of the reference substrate and the impedance of the bowed substrate deviates.

In another embodiment, a method for determining semiconductor process chamber parameters includes positioning a reference substrate on an electrostatic chuck in a process chamber; positioning a bowed substrate on the reference substrate; monitoring an impedance of the reference substrate and an impedance of the bowed substrate using the sensor; incrementally decreasing a voltage of the power until the impedance of the reference substrate and the impedance of the bowed substrate deviates; and determining process parameters of the process chamber when the impedance of the reference substrate and the impedance of the bowed substrate deviates.

In another embodiment, a setup for monitoring electrostatic chuck performance in a process chamber includes a reference substrate on an electrostatic chuck in the process chamber; a bowed substrate on the reference substrate; a sensor positioned between the electrostatic chuck and ground; a power source configured to supply power to an electrode in the electrostatic chuck; and a controller configured to regulate operation of the process chamber, wherein the controller comprises a memory containing instructions for execution on a processor comprising: monitoring an impedance of the reference substrate and an impedance of the bowed substrate using the sensor; and incrementally decreasing a voltage from the power source until the impedance of the reference substrate and the impedance of the bowed substrate deviates.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic sectional view of a process chamber for processing a semiconductor substrate according to at least one embodiment described in the present disclosure;

FIG. 2A is a graph illustrating the impedance of the reference wafer and the bowed wafer shown in FIG. 1 as a function of time according to at least one embodiment described in the present disclosure;

FIG. 2B is a graph illustrating the voltage from the power source shown in FIG. 1 as a function of time according to at least one embodiment described in the present disclosure; and

FIG. 3 is a method for monitoring electrostatic chucking performance according to at least one embodiment described in the present disclosure.

### DETAILED DESCRIPTION

In the following description, numerous specific details are set forth to provide a more thorough understanding of the embodiments of the present disclosure. However, it will be apparent to one of skill in the art that one or more of the embodiments of the present disclosure may be practiced without one or more of these specific details. In other instances, well-known features have not been described in order to avoid obscuring one or more of the embodiments of the present disclosure.

Embodiments described herein generally relate to methods and tools for monitoring electrostatic chucking performance within semiconductor processes. In embodiments described herein, an electrostatic chucking performance test is performed that requires only one bowed substrate and one reference substrate. To run the test, the reference substrate is positioned on an electrostatic chuck in a process chamber and the bowed substrate is positioned on the reference substrate. A sensor is positioned between the electrostatic chuck and ground while a power source is configured to supply power to an electrode in the electrostatic chuck. A voltage is applied from the power source to the electrostatic chuck, generating an electrostatic chucking force to secure the bowed substrate to the reference substrate.

Initially, a high electrostatic chuck voltage is applied for an amount of time to stabilize the substrates. Thereafter, the electrostatic chucking voltage reduces incrementally over certain intervals of time. Reducing the electrostatic chucking voltage reduces the electrostatic chucking force on the substrates. Below a certain voltage threshold, the electrostatic chucking force is too weak to maintain the bowed substrate in flat form, resulting in dechucking of the bowed wafer. When the bowed wafer starts to dechuck, the edge of the bowed wafer starts to warp up, allowing more current to flow between the bowed substrate and the electrostatic chuck. As a result, the chamber impedance decreases due to a change in plasma coupling. By monitoring the impedance of the chamber during deposition using the sensor, the dechucking threshold voltage can be identified at the point where the impedance of the reference substrate and the impedance of the bowed substrate deviates.

The electrostatic chucking performance test as described in embodiments herein provides many benefits. First, as mentioned above, the performance tests described herein only require one reference substrate and one bowed substrate rather than multiple bowed substrates required in conventional tests. Additionally, for comparing chamber hardware and chamber process parameters, the performance test can be conducted once or few times to acquire accurate information. As such, methods and tools can be used for multiple hardware and process parameter evaluation across different chambers in a much shorter time with more reliable results. The performance tests are especially useful in systems where established controls are prohibitive due to the hardware design and high temperatures.

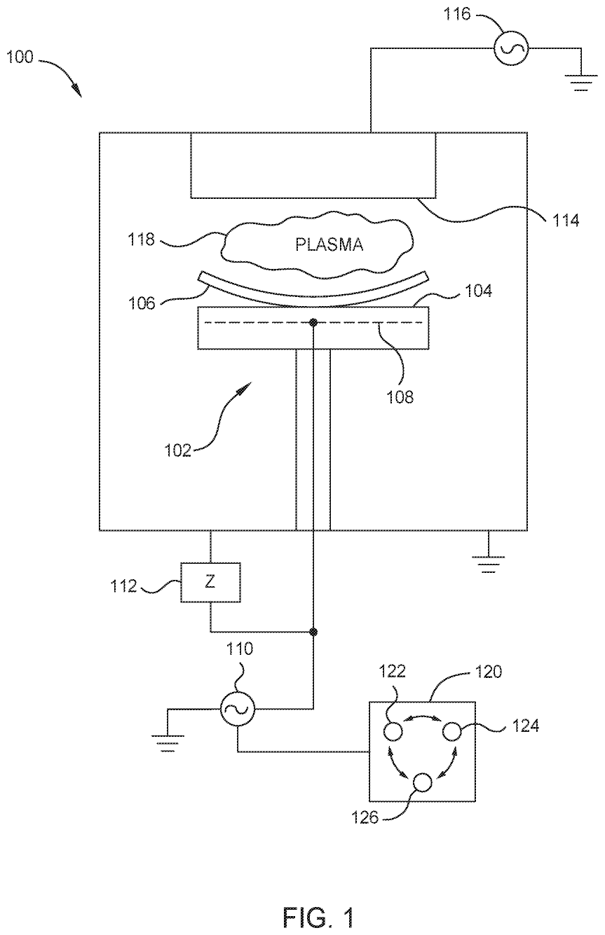

FIG. 1 is a schematic sectional view of a process chamber 100 for processing a semiconductor substrate according to at least one embodiment described in the present disclosure. The figure illustrates a substrate bowing scenario during a plasma process. The process chamber 100 includes an electrostatic chuck 102, a reference substrate 104, and a bowed substrate 106. The reference substrate 104 is positioned on the electrostatic chuck 102 and the bowed substrate 106 is positioned on the reference substrate 104. The reference substrate 104 can be made of silicon (Si), but can be other similar materials. The bowed substrate 106 can be made of Si with Tetraethyl orthosilicate (TEOS) based oxide film on top, but can be other similar materials and/or use other similar oxides. The bowed substrate 106 can have a thickness of about 7-9 micrometers, although other similar substrate thicknesses can be used.

An electrode 108 is contained within the electrostatic chuck 102 connected to a RF power supply 110. When proper RF power is applied to the electrode 108, a plasma may be generated from any precursor gas supplied in a plasma region 118 between the electrostatic chuck 102 and a faceplate 114. A power supply 116 can be applied to the faceplate 114 within the process chamber 100 to excite the precursor gas into a plasma. The temperature within the process chamber 100 during processing can be between about 400 degrees Celsius (C) to about 700 degrees C., although other processing temperatures are possible. With such high temperatures, the warped edges of the bowed substrate 106 can rise easily. The bowing presents a challenge for process uniformity, which becomes increasingly critical as feature size shrinks. Therefore, the electrostatic chuck 102 acts to keep the bowed wafer 106 flat during processing. The electrostatic chuck 102 provides a chucking force by applying a voltage to the electrode 108 embedded within in the electrostatic chuck 102, which generates a DC-based electrostatic force to secure the bowed substrate 106 to the reference substrate 104. In one embodiment, the electrode 108 is RF mesh.

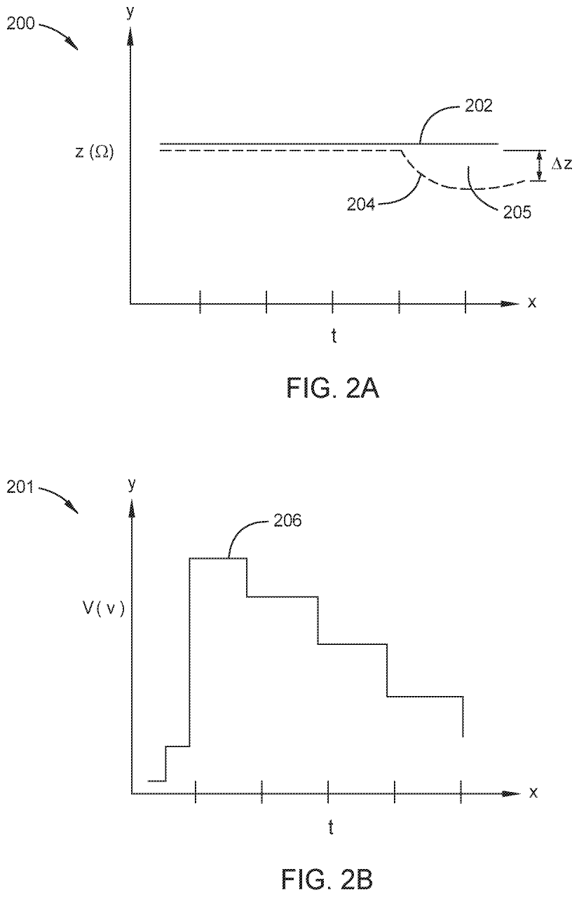

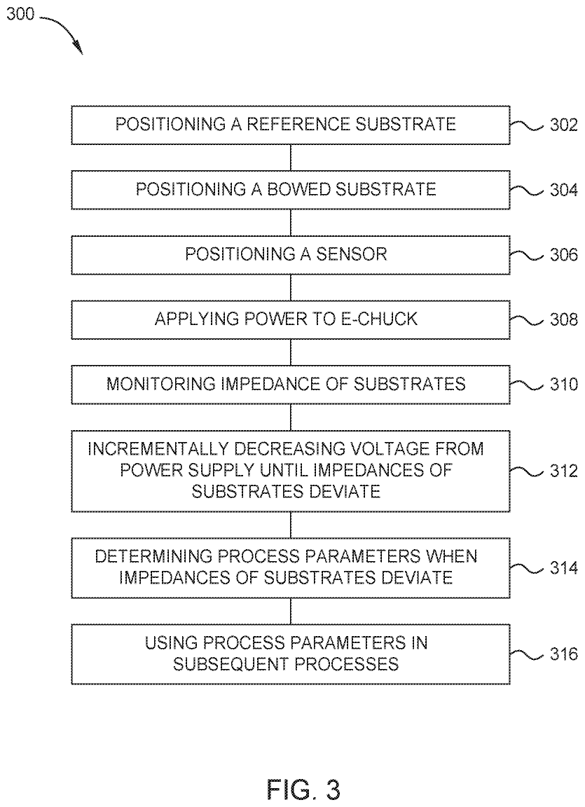

The process chamber 100 also includes a sensor 112. The sensor 112 is positioned between the electrostatic chuck 102 and ground and is configured to monitor the impedances of the reference substrate 104 and the bowed substrate 106 which will be described in more detail in FIG. 2A. Additionally, the process chamber 100 includes a controller 120. The controller 120 is configured to monitor the operation of the process chamber 100 and includes a central processing unit (CPU) 122, a memory 124, and support circuits 126. The CPU 122 can be any form of a general-purpose computer processor that may be used in an industrial setting. Software routines can be stored in the memory 124, which may be a random access memory, a read-only memory, floppy, a hard disk drive, or other form of digital storage. The software routines are executed on the CPU 122 and can include execution of the method steps described below in FIG. 3. The support circuits 126 are coupled to the CPU 122 and may include cache, clock circuits, input/output systems, power supplies, and the like.

FIG. 2A is a graph 200 illustrating the impedance of the reference wafer 104 and the bowed wafer 106, shown in FIG. 1, as a function of time according to at least one embodiment described in the present disclosure. FIG. 2B is a graph 201 illustrating the voltage from the power source 110 shown in FIG. 1 as a function of time according to at least one embodiment described in the present disclosure. As described above, the sensor 112 (FIG. 1) monitors a reference substrate impedance 202 and a bowed substrate impedance 204 shown in FIG. 2A. The power source 110 supplies the voltage 206 shown in FIG. 2B.

The voltage 206 is initially high for an amount of time to stabilize the substrates. The initial voltage can be 1000 volts (V) or other similar voltages. Thereafter, the voltage 206 is incrementally decreased in a step down manner as shown in the graph 201. For example, the voltage 206 can be reduced 50V at 20 second (s) intervals. In other examples, the voltage 206 can be reduced 100V at 30 s intervals or can be reduced 25V at 10 s intervals. The intervals between the voltage reductions are advantageous because they provide a stabilization time period for the process to adjust. However, the voltage reductions can also be configured to change continuously with time. The voltage 206 is reduced until the reference substrate impedance 202 and the bowed wafer impedance 204 deviate, as is shown in the graph 200 in region 205. In general, the greater the voltage 206 can be reduced until the impedances deviate, the better the electrostatic chucking performance. The voltage at which the impedances deviate is called the “threshold voltage.” In some embodiments, the impedances deviate at about 550V. In other embodiments, the impedances deviate at about 300V. However, these are just examples and the impedances can deviate at many different threshold voltages.

FIG. 3 is a method 300 for monitoring electrostatic chucking performance according to at least one embodiment described in the present disclosure. In these embodiments, the method 300 is performed with the devices described in FIG. 1, but is not limited to these devices and can be performed with other similar devices. In block 302, the reference substrate 104 is positioned on the electrostatic chuck 102 in the process chamber 100. In block 304, the bowed substrate 106 is positioned on the reference substrate 104. In block 306, the sensor 112 is positioned between the electrostatic chuck 102 and ground. In block 308, a voltage is applied from the power source 110 to the electrode 108 in the electrostatic chuck 102. In block 310, the reference substrate impedance 202 and the bowed substrate impedance 204 are monitored using the sensor 112. In block 312, the applied voltage is reduced by the power source 110 in increments until the reference substrate impedance 202 and the bowed substrate impedance 204 deviates.

In optional block 314, the process parameters of the process chamber 100 are determined when the reference substrate impedance 202 and the bowed substrate impedance 204 deviates. In optional block 316, the process parameters are used in subsequent process chamber applications. As such, the process parameters determined in block 314 can allow a user to preset the process chamber parameters to ensure optimal electrostatic chucking performance. The subsequent process chamber applications can be performed in the same process chamber at a future time, or can be applied to different chambers for testing of electrostatic chucking performance using the block 314 process parameters.

While the foregoing is directed to embodiments of the present disclosure, other and further embodiments of the disclosure may be devised without departing from the basic scope thereof, and the scope thereof is determined by the claims that follow.

We claim:

1. A method for monitoring electrostatic chucking performance, comprising:
positioning a reference substrate on an electrostatic chuck in a process chamber;
positioning a bowed substrate on the reference substrate;
applying a power to an electrode in the electrostatic chuck;
monitoring an impedance of the reference substrate and an impedance of the bowed substrate using a sensor positioned between the electrostatic chuck and ground; and
incrementally decreasing a voltage of the power until the impedance of the reference substrate and the impedance of the bowed substrate deviates.

2. The method of claim 1, wherein the voltage is initially set at about 1000V.

3. The method of claim 2, wherein the voltage is reduced about 50V at 20 s intervals.

4. The method of claim 2, wherein the voltage is reduced about 100V at 30 s intervals.

5. The method of claim 2, wherein the voltage is reduced about 25V at 10 s intervals.

6. The method of claim 1, wherein the process chamber temperature is maintained at between about 400 C and about 700 C.

7. A method for determining semiconductor process chamber parameters, comprising:
positioning a reference substrate on an electrostatic chuck in a process chamber;
positioning a bowed substrate on the reference substrate;
applying a power to an electrode in the electrostatic chuck;
monitoring an impedance of the reference substrate and an impedance of the bowed substrate using a sensor positioned between the electrostatic chuck and ground;
incrementally decreasing a voltage of the power until the impedance of the reference substrate and the impedance of the bowed substrate deviates; and
determining process parameters of the process chamber when the impedance of the reference substrate and the impedance of the bowed substrate deviates.

8. The method of claim 7, further comprising using the process parameters in subsequent semiconductor processes.

9. The method of claim 7, wherein the voltage is initially set at about 1000V.

10. The method of claim 9, wherein the voltage is reduced about 50V at 20 s intervals.

11. The method of claim 9, wherein the voltage is reduced about 100V at 30 s intervals.

12. The method of claim 9, wherein the voltage is reduced about 25V at 10 s intervals.

13. The method of claim 7, wherein the process chamber temperature is maintained between about 400 C and about 700 C.

14. A setup for monitoring electrostatic chuck performance in a process chamber, comprising:
a reference substrate on an electrostatic chuck in the process chamber;
a bowed substrate on the reference substrate;
a sensor positioned between the electrostatic chuck and ground;
a power source configured to supply power to an electrode in the electrostatic chuck; and
a controller configured to regulate operation of the process chamber, wherein the controller comprises a memory containing instructions for execution on a processor comprising:
monitoring an impedance of the reference substrate and an impedance of the bowed substrate using the sensor; and
incrementally decreasing a voltage from the power source until the impedance of the reference substrate and the impedance of the bowed substrate deviates.

15. The setup of claim 14, wherein the process chamber temperature is maintained between about 400 C and about 700 C.

16. The setup of claim 14, wherein the voltage is initially set at about 1000V.

17. The setup of claim 16, wherein the voltage is reduced about 50V at 20 s intervals.

18. The setup of claim 16, wherein the voltage is reduced about 100V at 30 s intervals.

19. The setup of claim 16, wherein the voltage is reduced about 25V at 10 s intervals.
